(19) United States
(12) Patent Application Publication
(10) Pub. No.: US 2006/0192280 A1
(43) Pub. Date: Aug. 31, 2006

(54) Method of forming electronic devices

(75) Inventors: David Richard Esler, Mayfield, NY (US); Donald Joseph Buckley JR., Schenectady, NY (US); Sandeep Shrikant Tonapi, Niskayuna, NY (US); John Robert Campbell, Clifton Park, NY (US); Ryan Christopher Mills, Rexford, NY (US); Ananth Prabhakumar, Schenectady, NY (US); Arun Virupaksha Gowda, Schenectady, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company

(21) Appl. No.: 11/068,376

(22) Filed: Feb. 28, 2005

(51) Int. Cl. H01L 23/48; H01L 21/58

(52) U.S. Cl. 257/701; 438/613; 438/125; 257/737; 257/778

(57) ABSTRACT

A method of forming polymer reinforced solder-bumped containing device or substrate is described. The method comprises the following steps: providing a device or substrate having at least one solder bump formed thereon; coating a predetermined portion of the device or substrate with a curable polymer reinforcement material forming a layer on the device or substrate, partially curing the curable polymer reinforcement material to provide a solder-bumped structure comprising a partially cured polymer reinforcement material, and, making a connection between the solder-bumped structure formed and a printed circuit board or array of attachment pads and fully curing the partially cured polymer reinforcement material to provide a reinforced interconnection. Full curing of the polymer reinforcement material may take place either during the “reflow step” or subsequent to it (post-curing).

### BACKGROUND OF THE INVENTION

This invention is related to a method of forming an electronic device comprising a reinforced interconnection. In one aspect, this invention relates to a filled, curable polymer material for solder joint reinforcement in solder-bumped devices.

Demand for smaller and more sophisticated electronic devices continues to drive the electronic industry towards improved integrated circuit packages that are capable of supporting higher input/output density as well as have enhanced performance at smaller device areas. To cope with such a requirement, an arrangement involving a large number of devices joined to the printed circuit board through solder joints disposed in a grid like arrangement on connecting terminals is typically used. The reliability of these solder joints is a function of various design, material, and process factors, including the silicon chip size within the device, printed circuit board thickness, and assembly parameters. The solder joints that connect the device and the printed circuit board are subject to thermomechanical stresses during device operation, due to differences in coefficients of thermal expansion (CTE) between the device and the printed circuit board. Thus, the primary mode of failure is solder joint fatigue. The solder joints almost always fail at the solder joint-solder mask interface towards the device side, due to stress concentrations arising from a solder mask defined (SMD) attachment pad on the device side. Reinforcing this interface, at the base of the solder joint towards the device side, with a high modulus, low thermal expansion, and high glass transition material enhances the life of the solder joints significantly.

This problem has been addressed and several solutions have been put forward, but some of these solutions require redesign of the device, while others involve additional assembly processes. These processes add cost to the final product. Thus, there is a need in the art to develop systems that improve the reinforcement of the solder-bumped devices that is simple in its solution and does not increase the cost of the product significantly.

### BRIEF SUMMARY OF THE INVENTION

In one aspect, the invention provides a method of forming an electronic device comprising a solder-bumped structure, said method comprising the steps of:

(A) providing a substrate having at least one solder bump formed thereon, said solder bump comprising at least one exposed surface;

(B) coating a predetermined portion of the substrate with a curable polymer reinforcement material to form a layer of the curable polymer reinforcement material on the substrate, said layer contacting the exposed surface of said at least one solder-bump;

(C) partially curing the curable polymer reinforcement material to provide a solder-bumped structure; and

(D) making a connection between the solder-bumped structure and a printed circuit board or array of attachment pads and subsequently fully curing the curable polymer reinforcement material to provide an interconnection that is reinforced with fully cured polymer reinforcement material.

### BRIEF DESCRIPTION OF THE DRAWINGS

FIGS. 1, 2 and 3 show the following sequence of drawings that illustrates the creation of the polymer-reinforced electronic device comprising a solder-bumped structure. FIG. 1 shows a step in the method of the invention which is the application of the curable polymer reinforcement material to the substrate.

FIG. 2 shows a step of the method of the invention in which the curable polymer reinforcement material is partially cured (“B-staged”) to provide a solder-bumped structure.

FIG. 3 shows a step of the method of the invention in which a connection between the solder-bumped structure and a printed circuit board or array of attachment pads is made followed by fully curing the curable polymer reinforcement material to provide an interconnection comprising a plurality of reinforced solder joints that is reinforced with fully cured polymer reinforcement material.

FIG. 4 illustrates a reinforced solder joint prepared according to the method of the invention.

FIG. 5 shows a time versus temperature plot of the solder reflow process, during which process, the solder-bumped substrate is attached to the printed circuit board. The horizontal axis represents the time in minutes and the vertical axis represents the temperature in degrees Celsius.

FIG. 6 shows a plot of unreliability function versus cycles to failure, which is used to determine the number of cycles to failure. The vertical axis represents the unreliability function or the Weibull cumulative density function (cdf) expressed as a percentage. The horizontal axis represents the cycles to failure in lognormal scale.

### DETAILED DESCRIPTION OF THE INVENTION

The invention may be understood more readily by reference to the following detailed description of preferred embodiments of the invention and the examples included therein. In the following specification and the claims which follow, reference will be made to a number of terms which shall be defined to have the following meanings:

The singular forms “a”, “an” and “the” include plural referents unless the context clearly dictates otherwise.

“Optional” or “optionally” means that the subsequently described event or circumstance may or may not occur, and that the description includes instances where the event occurs and instances where it does not.

As used herein the term “aliphatic radical” refers to an organic radical having a valence of at least one consisting of a linear or branched array of atoms which is not cyclic. Aliphatic radicals are defined to comprise at least one carbon atom. The array of atoms comprising the aliphatic radical may include heteroatoms such as nitrogen, sulfur, silicon, selenium and oxygen or may be composed exclusively of carbon and hydrogen. For convenience, the term “aliphatic radical” is defined herein to encompass, as part of the “linear or branched array of atoms which is not cyclic” a wide range of functional groups such as alkyl groups, alkenyl groups, alkynyl groups, halo alkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups and the like. For example, the 4-methylpent-1-yl radical is a C₆ aliphatic radical comprising a methyl group, the methyl group being a functional group which is an alkyl group. Similarly, the 4-nitrobut-1-yl group is a C₄ aliphatic radical comprising a nitro group, the nitro group being a functional group. An aliphatic radical may be a haloalkyl group which comprises one or more halogen atoms which may be the same or different. Halogen atoms include, for example; fluorine, chlorine, bromine, and iodine. Aliphatic radicals comprising one or more halogen atoms include the alkyl halides trifluoromethyl, bromodifluoromethyl, chlorodifluoromethyl, hexafluoroisopropylidene, chloromethyl; difluorovinylidene; trichloromethyl, bromodichloromethyl, bromoethyl, 2-bromotrimethylene (e.g. —CH₂CHBrCH₂—), and the like. Further examples of aliphatic radicals include allyl, aminocarbonyl (i.e. —CONH₂), carbonyl, dicyanoisopropylidene (i.e. —CH₂C(CN)₂CH₂—), methyl (i.e. —CH₃), methylene (i.e. —CH₂—), ethyl, ethylene, formyl (i.e.—CHO), hexyl, hexamethylene, hydroxymethyl (i.e.—CH₂OH), mercaptomethyl (i.e. —CH₂SH), methylthio (i.e. —SCH₃), methylthiomethyl (i.e. —CH₂SCH₃), methoxy, methoxycarbonyl (i.e. CH₃OCO—) , nitromethyl (i.e. —CH₂NO₂), thiocarbonyl, trimethylsilyl ( i.e.(CH₃)₃Si—), t-butyldimethylsilyl, trimethyoxysilypropyl (i.e. (CH₃O)₃SiCH₂CH₂CH₂—), vinyl, vinylidene, and the like. By way of further example, a C₁-C₁₀ aliphatic radical contains at least one but no more than 10 carbon atoms. A methyl group (i.e. CH₃—) is an example of a C₁, aliphatic radical. A decyl group (i.e. CH₃(CH₂)₁₀—) is an example of a C₁₀ aliphatic radical.

As used herein, the term “aromatic radical” refers to an array of atoms having a valence of at least one comprising at least one aromatic group. The array of atoms having a valence of at least one comprising at least one aromatic group may include heteroatoms such as nitrogen, sulfur, selenium, silicon and oxygen, or may be composed exclusively of carbon and hydrogen. As used herein, the term “aromatic radical” includes but is not limited to phenyl, pyridyl, furanyl, thienyl, naphthyl, phenylene, and biphenyl radicals. As noted, the aromatic radical contains at least one aromatic group. The aromatic group is invariably a cyclic structure having 4n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), anthraceneyl groups (n=3) and the like. The aromatic radical may also include nonaromatic components. For example, a benzyl group is an aromatic radical which comprises a phenyl ring (the aromatic group) and a methylene group (the nonaromatic component). Similarly a tetrahydronaphthyl radical is an aromatic radical comprising an aromatic group (C₆H₃) fused to a nonaromatic component —(CH₂)₄—. For convenience, the term “aromatic radical” is defined herein to encompass a wide range of functional groups such as alkyl groups, alkenyl groups, alkynyl groups, haloalkyl groups, haloaromatic groups, conjugated dienyl groups, alcohol groups, ether groups, aldehydes groups, ketone groups, carboxylic acid groups, acyl groups (for example carboxylic acid derivatives such as esters and amides), amine groups, nitro groups, and the like. For example, the 4-methylphenyl radical is a C₇ aromatic radical comprising a methyl group, the methyl group being a functional group which is an alkyl group. Similarly, the 2-nitrophenyl group is a C₆ aromatic radical comprising a nitro group, the nitro group being a functional group. Aromatic radicals include halogenated aromatic radicals such as trifluoromethylphenyl, hexafluoroisopropylidenebis(4-phen-1-yloxy) (i.e. —OPhC(CF₃)₂PhO—), chloromethylphenyl; 3-trifluorovinyl-2-thienyl; 3-trichloromethylphen-1-yl (i.e. 3-CCl₃Ph—), 4(3-bromoprop-1-yl)phen-1-yl (i.e. BrCH₂CH₂CH₂Ph—), and the like. Further examples of aromatic radicals include 4-allyloxyphen-1-oxy, 4-aminophen-1-yl (i.e. H₂NPh—), 3-aminocarbonylphen-1-yl (i.e. NH₂COPh—), 4-benzoylphen-1-yl, dicyanoisopropylidenebis(4-phen-1-yloxy) (i.e. —OPhC(CN)₂PhO—), 3-methylphen-1-yl, methylenebis(phen-4-yloxy) (i.e. OPhCH₂PhO—), 2-ethylphen-1-yl, phenylethenyl, 3-formyl-2-thienyl, 2-hexyl-5-furanyl; hexamethylene-1,6-bis(phen-4-yloxy) (i.e. —OPh(CH₂)₆PhO—); 4-hydroxymethylphen-1-yl (i.e. 4-HOCH₂Ph—), 4-mercaptomethylphen-1-yl (i.e. 4-HSCH₂Ph—), 4-methylthiophen-1-yl (i.e. 4-CH₃SPh—), 3-methoxyphen-1-yl, 2-methoxycarbonylphen-1-yloxy (e.g. methyl salicyl), 2-nitromethylphen-1-yl (i.e. —PhCH₂NO₂), 3-trimethylsilylphen-1-yl, 4-t-butyldimethylsilylphenl-1-yl, 4-vinylphen-1-yl, vinylidenebis(phenyl), and the like. The term “a C₃—C₁₀ aromatic radical” includes aromatic radicals containing at least three but no more than 10 carbon atoms. The aromatic radical 1-imidazolyl (C₃H₂N₂—) represents a C₃ aromatic radical. The benzyl radical (C₇H₈—) represents a C₇ aromatic radical.

As used herein the term “cycloaliphatic radical” refers to a radical having a valence of at least one, and comprising an array of atoms which is cyclic but which is not aromatic. As defined herein a “cycloaliphatic radical” does not contain an aromatic group. A “cycloaliphatic radical” may comprise one or more noncyclic components. For example, a cyclohexylmethyl group (C₆H₁₁CH₂—) is an cycloaliphatic radical which comprises a cyclohexyl ring (the array of atoms which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. For convenience, the term “cycloaliphatic radical” is defined herein to encompass a wide range of functional groups such as alkyl groups, alkenyl groups, alkynyl groups, halo alkyl groups , conjugated dienyl groups, alcohol groups, ether groups, aldehyde groups, ketone groups, carboxylic acid groups, acyl groups (for example carboxylic acid derivatives such as esters and amides), amine groups, nitro groups and the like. For example, the 4-methylcyclopent-1-yl radical is a C₆ cycloaliphatic radical comprising a methyl group, the methyl group being a functional group which is an alkyl group. Similarly, the 2-nitrocyclobut-1-yl radical is a C₄ cycloaliphatic radical comprising a nitro group, the nitro group being a functional group. A cycloaliphatic radical may comprise one or more halogen atoms which may be the same or different. Halogen atoms include, for example; fluorine, chlorine, bromine, and iodine. Cycloaliphatic radicals comprising one or more halogen atoms include 2-trifluoromethylcyclohex-1-yl, 4-bromodifluoromethylcyclooct-1-yl, 2-chlorodifluoromethylcyclohex-1-yl, hexafluoroisopropylidene2,2-bis (cyclohex-4-yl) (i.e. —C₆H₁₀C(CF₃)₂ C₆H₁₀—), 2-chloromethylcyclohex-1-yl; 3-difluoromethylenecyclohex-1-yl; 4-trichloromethylcyclohex-1-yloxy, 4-bromodichloromethylcyclohex-1-ylthio, 2-bromoethylcyclopent-1-yl, 2-bromopropylcyclohex-1-yloxy (e.g. CH₃CHBrCH₂C₆H₁₀—), and the like. Further examples of cycloaliphatic radicals include 4-allyloxycyclohex-1-yl, 4-aminocyclohex-1-yl (i.e. H₂NC₆H₁₀—), 4-aminocarbonylcyclopent-1-yl (i.e. NH₂COC₅H₈—), 4-acetyloxycyclohex-1-yl, 2,2-dicyanoisopropylidenebis(cyclohex-4-yloxy) (i.e. —OC₆H₁₀C(CN)₂C₆H₁₀O—), 3-methylcyclohex-1-yl, methylenebis(cyclohex-4-yloxy) (i.e. —OC₆H₁₀CH₂C₆H₁₀O—), 1-ethylcyclobut-1-yl, cyclopropylethenyl, 3-formyl-2-terahydrofuranyl, 2-hexyl-5-tetrahydrofuranyl; hexamethylene-1,6-bis(cyclohex-4-yloxy) (i.e. —O C₆H₁₀(CH₂)₆C₆H₁₀O—); 4-hydroxymethylcyclohex-1-yl (i.e. 4-HOCH₂C₆H₁₀—), 4-mercaptomethylcyclohex-1-yl (i.e. 4-HSCH₂C₆H₁₀—), 4-methylthiocyclohex-1-yl (i.e. 4-HSCH₂C₆H₁₀—), 4-methoxycyclohex-1yl, 2-methoxycarbonylcyclohex-1-yloxy (2-CH₃OCOC₆H₁₀O—), 4-nitromethylcyclohex-1-yl (i.e. NO₂CH₂C₆H₁₀—), 3-trimethylsilylcyclohex-1-yl, 2-t-butyldimethylsilylcyclopent-1-yl, 4-trimethoxysilylethylcyclohex-1-yl (e.g. (CH₃O)₃SiCH₂CH₂C₆H₁₀O—), 4-vinylcyclohexen-1-yl, vinylidenebis(cyclohexyl), and the like. The term “a C₃—C₁₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

As noted, the present invention provides a method of forming an electronic device comprising a solder-bumped structure, said method comprising the steps of:

(A) providing a substrate having at least one solder-bump formed thereon, said solder-bump comprising at least one exposed surface;

(B) coating a predetermined portion of the substrate with a curable polymer reinforcement material to form a layer of the curable polymer reinforcement material on the substrate, said layer contacting the exposed surface of said at least one solder-bump;

(C) partially curing the curable polymer reinforcement material to provide a solder-bumped structure; and

(D) making a connection between the solder-bumped structure and a printed circuit board or array of attachment pads and subsequently fully curing the curable polymer reinforcement material to provide an interconnection that is reinforced with fully cured polymer reinforcement material.

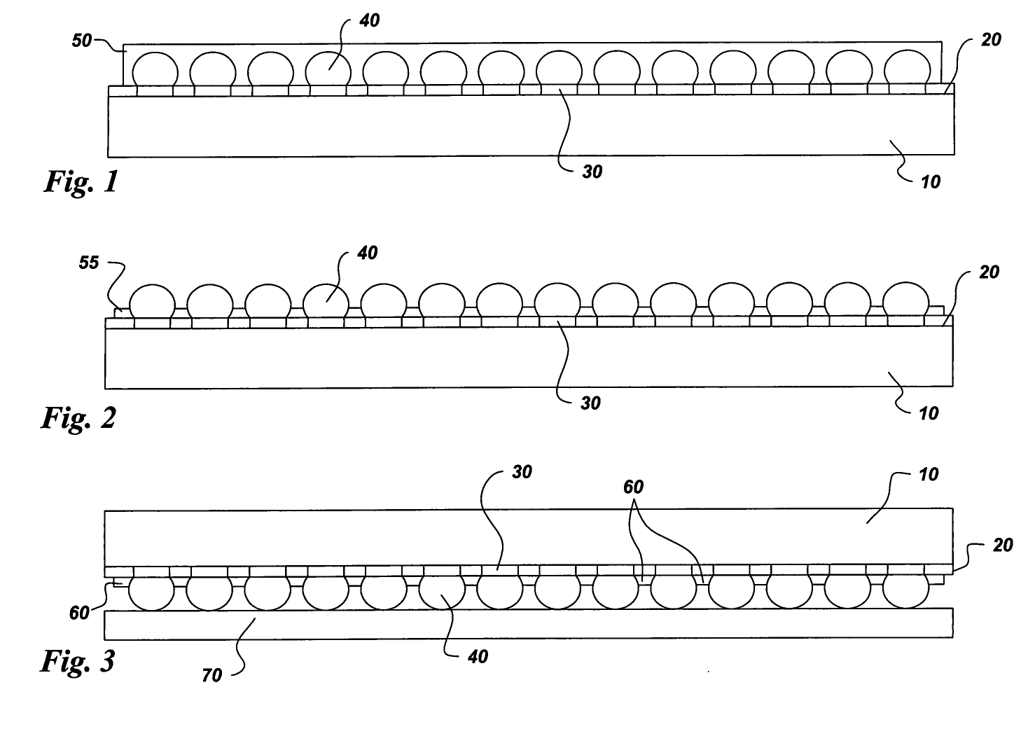

In a typical embodiment of the invention, a substrate having at least one solder-bump formed thereon (a “solder-bumped substrate”) is created by placing at least one solder ball onto an attachment pad on a substrate followed by a reflow step to melt the solder into place and form a solder-bump. Alternatively, the solder bump may be formed by applying solder paste and reflowing to melt the solder into place. The reinforcement of the solder-bump is subsequently achieved by coating a predetermined portion of the substrate with a curable polymer reinforcement material thereby forming a layer of the curable polymer reinforcement material on the substrate, said layer contacting the exposed surface solder-bump with the curable polymer reinforcement material (See the solder-bumped substrate prior to curing in FIG. 1), followed by partially curing (“B-staging”) the curable polymer reinforcement material (See the result of partial curing in FIG. 2). As used herein, “B-staging” refers to partially curing a curable material. A connection is then made between the solder-bumped structure and a printed circuit board or an array of attachment pads, and subsequently fully curing the curable polymer reinforcement material to provide an interconnection that is reinforced with a fully cured polymer reinforcement material. A reinforced solder joint is formed when a partially reinforced solder-bumped structure comprising the partially cured polymer reinforcement material (e.g. see FIG. 2) is assembled with a printed circuit board or array of attachment pads, and subsequently fully curing the polymer reinforcement material (see the assembly of a solder-bumped structure comprising the polymer reinforcement material and a printed circuit board in FIG. 3).

In another aspect, the invention provides a method of forming an electronic device comprising a solder-bumped structure , said method consisting essentially of the steps of:
(A) providing a substrate having at least one solder bump formed thereon, said solder bump comprising at least one exposed surface;
(B) coating a predetermined portion of the substrate with a curable polymer reinforcement material to form a layer of the curable polymer reinforcement material on the substrate, said layer contacting the exposed surface of said at least one solder bump;
(C) partially curing the curable polymer reinforcement material to provide a solder-bumped structure; and
(D) making a connection between the solder-bumped structure to a printed circuit board or array of attachment pads and fully curing the curable polymer reinforcement material to provide an interconnection that is reinforced with fully cured polymer reinforcement material.

In one embodiment, the curable polymer reinforcement material used to reinforce the solder-bumped structure comprises at least one epoxy resin, at least one particulate filler, at least one cure catalyst, and optional reagents.

Epoxy resins as described in the invention are curable monomers and oligomers that include any organic system or inorganic system with an epoxy functionality. The epoxy resins useful in the invention include those described in “Chemistry and technology of the Epoxy Resins,” B. Ellis (Ed.) Chapman Hall 1993, New York and “Epoxy Resins Chemistry and Technology,” C. May and Y. Tanaka, Marcell Dekker 1972, New York. Epoxy resins that can be used for the invention include those that could be produced by reaction of a hydroxyl, carboxyl or amine containing compound with epichlorohydrin, preferably in the presence of a basic catalyst, such as a metal hydroxide, for example sodium hydroxide. Also included are epoxy resins produced by reaction of a compound containing at least one and preferably two or more carbon-carbon double bonds with a peroxide, such as a peroxyacid.

Preferred epoxy resins for the invention are cycloaliphatic and aliphatic epoxy resins. Aliphatic epoxy resins include compounds that contain at least one aliphatic group and at least one epoxy group. Examples of aliphatic epoxy resins include butadiene oxide, dimethylpentane dioxide, diglycidyl ether, 1,4-butanediol glycidyl ether, diethylene glycol diglycidyl ether, and dipentene dioxide.

Cycloaliphatic epoxy resins are well known to the art and, as described herein, are compounds that contain at least about one cycloaliphatic group and at least one oxirane group. More preferred cycloalipahtic epoxy resins are compounds that contain about one cycloaliphatic group and at least two oxirane rings per molecule. Specific examples include 3-cyclohexenylmethyl-3-cyclohexenylcarboxylate diepoxide; 2-(3,4-epoxy)cyclohexyl-5,5-spiro-(3,4-epoxy)cyclohexane-m-dioxane; 3,4-epoxycyclohexylalkyl-3,4-epoxycyclohexanecarboxylate; 3,4-epoxy-6-methylcyclohexylmethyl-3,4-epoxy-6-methylcyclohexanecarboxylate; vinyl cyclohexanedioxide, bis(3,4-epoxycyclohexylmethyl)adipate; bis(3,4-epoxy-6-methylcyclohexylmethyl)adipate; exo-exo bis(2,3-epoxycyclopentyl)ether; endo-exo bis(2,3-epoxycyclopentyl) ether; 2,2-bis(4-(2,3-epoxypropoxy)cyclohexyl)propane; 2,6-bis(2,3-epoxypropoxycyclohexyl-p-dioxane); 2,6-bis(2,3-epoxypropoxy)norbornene; the diglycidylether of linoleic acid dimmer; limonene dioxide; 2,2-bis(3,4-epoxycyclohexyl) propane; dicyclopentadiene dioxide; 1,2-epoxy-6-(2,3-epoxypropoxy) hexahydro-4,7-methanoindane; p-(2,3-epoxy)cyclopentylphenyl-2,3-epoxypropylether; 1-(2,3-epoxypropoxy)phenyl-5,6-epoxyhexahydro-4,7-methanoindane; o-(2,3-epoxy) cyclopentylphenyl-2,3-epoxypropyl ether); 1,2-bis(5-(1,2-epoxy)-4,7- hexahydromethanoindanoxyl)ethane; cyclopentenylphenyl glycidyl ether; cyclohexanediol diglycidyl ether; and diglycidyl hexahydrophthalate.

Aromatic epoxy resins may also be used with the invention. Examples of epoxy resins useful in the invention include bisphenol-A epoxy resins, bisphenol-F epoxy resins, phenol novolac epoxy resins, cresol-novolac epoxy resins, biphenol epoxy resins, biphenyl epoxy resins, 4,4′-biphenyl epoxy resins, polyfunctional epoxy resins, divinylbenzene dioxide, and 2-glycidylphenylglycidyl ether. When resins, including aromatic, aliphatic and cycloaliphatic resins, are described throughout the specification and claims, either the specifically-named resin or molecules having a moiety of the named resin are envisioned.

Silicone-epoxy resins of the invention typically have the formula:
MₐM′_{b}D_{c}D′_{d}TₑT′_{f}Q_{g}
wherein the subscripts a, b, c, d, e, f and g are zero or a positive integer, subject to the limitation that the sum of the subscripts b, d and f is one or greater; where M has the formula:
R¹₃SiO_{1/2},
M′ has the formula:
   (Z)R ²₂SiO_{1/2},
D has the formula:
   R³₂SiO_{2/2},
D′ has the formula:
   (Z)R⁴SiO_{2/2},
T has the formula:
   R⁵SiO_{3/2},
T′ has the formula:
   (Z)SiO_{3/2},
   and Q has the formula SiO _{4/2}, where each R¹, R², R³, R⁴, R⁵ is independently at each occurrence a hydrogen atom, C₁₋₂₂ alkyl, C₁₋₂₂ alkoxy, C₂₋₂₂ alkenyl, C₆₋₁₄ aryl, C₆₋₂₂ alkyl-substituted aryl, and C₆₋₂₂ arylalkyl which groups may be halogenated, for example, fluorinated to contain fluorocarbons such as C₁₋₂₂ fluoroalkyl, or may contain amino groups to form aminoalkyls, for example aminopropyl or aminoethylaminopropyl, or may contain polyether units of the formula (CH₂CHR⁶O)ₖ where R⁶ is CH₃ or H and k is in a range from about 4 to about 20; and Z, independently at each occurrence, represents an epoxy group. The term “alkyl” as used in various embodiments of the invention is intended to designate both normal alkyl, branched alkyl, aralkyl, and cycloalkyl radicals. Normal and branched alkyl radicals are preferably those containing in a range from about 1 to about 12 carbon atoms, and include as illustrative non-limiting examples methyl, ethyl, propyl, isopropyl, butyl, tertiary-butyl, pentyl, neopentyl, and hexyl. Cycloalkyl radicals represented are preferably those containing in a range from about 4 to about 12 ring carbon atoms. Some illustrative non-limiting examples of these cycloalkyl radicals include cyclobutyl, cyclopentyl, cyclohexyl, methylcyclohexyl, and cycloheptyl. Preferred aralkyl radicals are those containing in a range from about 7 to about 14 carbon atoms; these include, but are not limited to, benzyl, phenylbutyl, phenylpropyl, and phenylethyl. Aryl radicals used in the various embodiments of the invention are preferably those containing in a range from about 6 to about 14 ring carbon atoms. Some illustrative non-limiting examples of these aryl radicals include phenyl, biphenyl, and naphthyl. An illustrative non-limiting example of a halogenated moiety suitable is trifluoropropyl. Combinations of epoxy monomers and oligomers may be used in the invention. A preferred epoxy resin in the invention is a cresol novolac epoxy resin.

In one embodiment, the curable polymer reinforcement material comprises a particulate filler. The particulate filler may be selected from the group consisting of fused silica, fumed silica, colloidal silica and combinations thereof. In a preferred embodiment of the invention, the filler is functionalized colloidal silica. Colloidal silica is a dispersion of submicron-sized silica (SiO₂) particles in an aqueous or other solvent medium. The colloidal silica contains up to about 85 weight % of silicon dioxide (SiO₂) and more typically up to about 80 weight % of silicon dioxide. The particle size of the colloidal silica is typically in a range between about 1 nanometers (nm) and about 250 nm, and more typically in a range between about 5 nm and about 150 nm.

The colloidal silica may be functionalized with an organoalkoxysilane to form an organofunctionalized colloidal silica. Organoalkoxysilanes used to functionalize the colloidal silica are included within the formula:
(R⁷)ₕSi(OR⁸)₄₋ₕ,
where R⁷ is independently at each occurrence a C₁—C₁₈ monovalent hydrocarbon radical optionally further functionalized with alkyl acrylate, alkyl methacrylate or epoxide groups or C₆—C₁₄ aryl or alkyl radical, R⁸ is independently at each occurrence a C₁—C₁₈ monovalent hydrocarbon radical or a hydrogen radical and “h” is a whole number from to 1 to 3 inclusive. Preferably, the organoalkoxysilanes included in the invention are 2-(3,4-epoxy cyclohexyl)ethyltrimethoxysilane, 3-glycidoxypropyltrimethoxysilane, phenyltrimethoxysilane, and methacryloxypropyltrimethoxysilane. A combination of functionality is possible. Typically, the organoalkoxysilane is present in a range between about 5 weight % and about 60 weight % based on the weight of silicon dioxide contained in the colloidal silica. The resulting organofunctionalized colloidal silica can be treated with an acid or base to modify its properties . An acid, a base, or other catalyst effective at promoting condensation of silanol and alkoxysilane groups may also be used to aid the functionalization process. Such catalysts include organo-titanium compounds such as tetrabutyl titanate, and titanium isopropoxybis(acetylacetonate). Suitable catalysts also include and organo-tin compounds such as dibutyltin dilaurate. In one embodiment the catalyst comprises a combination of at least one organo-titanium compound and at least one organ-tin compound.

The functionalization of the colloidal silica may be performed by adding the organoalkoxysilane functionalization agent to an aqueous dispersion of colloidal silica to which an aliphatic alcohol has been added. The resulting composition comprising the functionalized colloidal silica and the organoalkoxysilane functionalization agent in the aliphatic alcohol is defined herein as a pre-dispersion. The aliphatic alcohol is typically an aliphatic alcohol selected from the group consisting of isopropanol, t-butanol, 2-butanol, and combinations thereof. The amount of aliphatic alcohol is typically employed in an amount corresponding to from about 1 fold to about 10 fold by weight of the amount of silicon dioxide present in the aqueous colloidal silica pre-dispersion. In some cases, stabilizers such as 4-hydroxy-2,2,6,6-tetramethylpiperidinyloxy (i. e. 4-hydroxy TEMPO) may be added to this pre-dispersion. In some instances small amounts of acid or base may be added to adjust the pH of the transparent pre-dispersion. “Transparent” as used herein refers to a maximum haze value of 15%, typically a maximum haze value of 10%; and most typically a maximum haze value of 3%, as measured by the standard test method described in ASTM D1003. The resulting pre-dispersion is typically heated from about 50° C. to about 100° C. for a period of from about 1 hour to about 5 hours.

The cooled transparent organic pre-dispersion is then further treated to form a final dispersion of the functionalized colloidal silica by addition of curable epoxy monomers or oligomers and optionally, more aliphatic solvent which may be selected from but not limited to isopropanol, 1-methoxy-2-propanol, 1-methoxy-2-propyl acetate, toluene, and combinations thereof. This final dispersion of the functionalized colloidal silica may be treated with acid or base or with ion exchange resins to remove acidic or basic impurities. This final dispersion of the functionalized colloidal silica is then concentrated under a vacuum in a range between about 0.5 Torr and about 250 Torr and at a temperature in a range between about 20° C. and about 140° C. to substantially remove any low boiling components such as solvent, residual water, and combinations thereof to give a transparent dispersion of functionalized colloidal silica in a curable epoxy monomer, herein referred to as a final concentrated dispersion. Substantial removal of low boiling components is defined herein as removal of at least about 90% of the total amount of low boiling components.

In some instances, the pre-dispersion or the final dispersion of the functionalized colloidal silica may be further functionalized. Low boiling components are at least partially removed and subsequently, an appropriate capping agent that will react with residual hydroxyl functionality of the functionalized colloidal silica is added in an amount in a range between about 0.05 times and about 10 times the amount by weight of silicon dioxide present in the pre-dispersion or final dispersion. Partial removal of low boiling components as used herein refers to removal of at least about 10% of the total amount of low boiling components, and preferably, at least about 50% of the total amount of low boiling components. An effective amount of capping agent caps the functionalized colloidal silica and capped functionalized colloidal silica is defined herein as a functionalized colloidal silica in which at least 10%, preferably at least 20%, more preferably at least 35%, of the free hydroxyl groups present in the corresponding uncapped functionalized colloidal silica have been functionalized by reaction with a capping agent.

Exemplary capping agents include hydroxyl reactive materials such as silylating agents. Examples of a silylating agent include, but are not limited to hexamethyldisilazane (HMDZ), tetramethyldisilazane, divinyltetrametyldisilazane, diphenyltetramethyldisilazane, N-(trimethylsilyl)diethylamine, 1-(trimethylsilyl)imidazole, trimethylchlorosilane, pentamethylchlorodisiloxane, pentamethyldisiloxane, and combinations thereof. The transparent dispersion is then heated in a range between about 20° C. and about 140° C. for a period of time in a range between about 0.5 hours and about 48 hours. The resultant mixture is then filtered. If the pre-dispersion was reacted with the capping agent, at least one curable epoxy monomer is added to form the final dispersion. The mixture of the functionalized colloidal silica in the curable monomer is concentrated at a pressure in a range between about 0.5 Torr and about 250 Torr to form the final concentrated dispersion. During this process, lower boiling components such as solvent, residual water, byproducts of the capping agent and hydroxyl groups, excess capping agent, and combinations thereof are substantially removed.

In order to form the total curable epoxy formulation, a cure catalyst is added to the final concentrated dispersion. Cure catalysts accelerate curing of the total curable epoxy formulation. Typically, the catalyst is present in a range between about 10 parts per million (ppm) and about 10% by weight of the total curable epoxy formulation. Examples of cure catalysts include, but are not limited to, onium catalysts such as bisaryliodonium salts e.g. bis(dodecylphenyl) iodonium hexafluoroantimonate, octyloxyphenyl iodonium hexafluoroantimonate, phenyl iodonium hexafluoroantimonate, bisaryliodonium tetrakis(pentafluorophenyl)borate, triarylsulphonium salts, and combinations thereof. Preferably, the catalyst is a bisaryliodonium salt. Optionally, an effective amount of a free-radical generating compound can be added as the optional reagent such as aromatic pinacols, benzoinalkyl ethers, organic peroxides, and combinations thereof. The free radical generating compound facilitates decomposition of onium salt at lower temperature.

Optionally, an epoxy hardener such as carboxylic acid- anhydride curing agents and an organic compound containing hydroxyl moiety are present as optional reagents with the cure catalyst. In these cases, cure catalysts may be selected from typical epoxy curing catalysts that include, but are not limited to amines, alkyl-substituted imidazole, imidazolium salts, phosphines, metal salts, and combinations thereof. Preferred catalysts include, but are not limited to, triphenyl phosphine, alkyl-imidazole, aluminum acetyl acetonate, and combinations thereof.

Exemplary anhydride curing agents typically include methylhexahydrophthalic anhydride, 1,2-cyclohexanedicarboxylic anhydride, bicyclo[2.2.1]hept-5-ene-2,3-dicarboxylic anhydride, methylbicyclo[2.2.1] hept-5-ene-2,3-dicarboxylic anhydride, phthalic anhydride, pyromellitic dianhydride, hexahydrophthalic anhydride, dodecenylsuccinic anhydride, dichloromaleic anhydride, chlorendic anhydride, tetrachlorophthalic anhydride, and the like. Combinations comprising at least two anhydride curing agents may also be used. Illustrative examples are described in “Chemistry and Technology of the Epoxy Resins” B. Ellis (Ed.) Chapman Hall, New York, 1993 and in “Epoxy Resins Chemistry and Technology”, C. A. May (Ed.), Marcel Dekker, New York, 2nd edition, 1988.

Examples of organic compounds containing hydroxyl moiety include diols of the formula HO—W—OH, wherein W is a C₁—C₂₀ divalent aliphatic radical, a C₃—C₄₀ divalent cycloaliphatic radical, or a C₃—C₄₀ divalent aromatic radical. Examples of such diols include aromatic bisphenols generally, and aliphatic and cyclo aliphatic diols. Aliphatic diols are illustrated by but are not limited to ethylene glycol; propylene glycol, i.e., 1,2- and 1,3-propylene glycol; 2,2-dimethyl-1,3-propane diol; 2-ethyl, 2-methyl, 1,3-propane diol; 1,3- and 1,5-pentane diol; dipropylene glycol; 2-methyl-1,5-pentane diol; and 1,6-hexane diol; triethylene glycol; 1,10-decane diol and mixtures thereof Cycloaliphatic diols are illustrated by but are not limited to 1,1-decalindimethanol, 2,2-bicyclooctanedimethanol; cis- 1,4-cyclohexanedimethanol; trans-1,4-cyclohexanedimethanol; and mixtures thereof. In one embodiment a mixture of diols comprising at least 2 diols selected from the group consisting of bisphenols, aliphatic diols, and cycloaliphatic diols is employed.

Some preferred examples of bisphenols include 1,1-bis(4-hydroxyphenyl)-3,3,5-trimethylcyclohexane; 2,2-bis(4-hydroxyphenyl)propane (commonly known as bisphenol A); 2,2-bis(4-hydroxy-3,5-dimethylphenyl)propane; 2,4′-dihydroxydiphenylmethane; bis(2-hydroxyphenyl)methane; bis(4-hydroxyphenyl)methane; bis(4-hydroxy-5-nitrophenyl)methane; bis(4-hydroxy-2,6-dimethyl-3-methoxyphenyl)methane; 1,1-bis(4-hydroxyphenyl) ethane; 1,1-bis(4-hydroxy-2-chlorophenyl)ethane; 2,2-bis(3-phenyl-4-hydroxyphenyl)propane; bis(4-hydroxyphenyl) cyclohexylmethane; 2,2-bis(4-hydroxyphenyl)-1-phenylpropane; 2,2,2 ′, 2′-tetrahydro-3 ,3 ,3′, 3′-tetramethyl- 1,1 ′-spirobi[1H-indene]-6,6′-diol (commonly known as SBI); 2,2-bis(4-hydroxy-3-methylphenyl)propane (commonly known as DMBPC); resorcinol; and C₁—C₃ alkyl-substituted resorcinols. Most typically, 2,2-bis(4-hydroxyphenyl)propane (BPA) is the preferred bisphenol compound. Combinations of organic compounds containing hydroxyl moieties can also be used.

A reactive organic diluent may also be added to the total curable epoxy formulation to decrease the viscosity of the composition. Examples of reactive diluents include, but are not limited to, 3-ethyl-3-hydroxymethyl-oxetane, dodecylglycidyl ether, 4-vinyl-1-cyclohexane diepoxide, di(β-(3,4-epoxycyclohexyl)ethyl)-tetramethyldisiloxane, and combinations thereof. An unreactive diluent may also be added to the composition to decrease the viscosity of the formulation. Examples of unreactive diluents include, but are not limited to toluene, ethyl acetate, butyl acetate, 1-methoxy propyl acetate, ethylene glycol, dimethyl ether, and combinations thereof.

As noted, the curable polymer reinforcement material may comprise a filler. Suitable fillers include, for example, fumed silica, fused silica such as spherical fused silica, alumina, carbon black, graphite, silver, gold, aluminum, mica, titania, diamond, silicone carbide, aluminum hydrates, boron nitride, and combinations thereof. When present, the filler is typically present in a range between about 10 weight % and about 95 weight %, based on the total weight of the formulation. More typically, the filler is present in a range between about 20 weight % and about 85 weight %, based on the total weight of the curable polymer reinforcement material.

The curable polymer reinforcement material may further comprise adhesion promoters such as trialkoxyorganosilanes e.g. omega-aminopropyltrimethoxysilane, 3-glycidoxypropyltrimethoxysilane, bis(trimethoxysilylpropyl)fumarate, and combinations thereof used in an effective amount which is typically in a range between about 0.01% by weight and about 2% by the total weight of the curable polymer reinforcement material.

Flame retardants may optionally be used in a range between about 0.5 weight % and about 20 weight % relative to the total weight of the polymer reinforcement material. Examples of flame retardants include phosphoramides, triphenyl phosphate (TPP), resorcinol diphosphate (RDP), bisphenol-A-disphosphate (BPA-DP), organic phosphine oxides, halogenated epoxy resin, metal oxide, metal hydroxides, and combinations thereof.

The curable polymer reinforcement material may prepared by hand mixing the components but also can be prepared using standard mixing equipment such as dough mixers, chain can mixers, planetary mixers, twin screw extruders, roll mills and the like. The blending can be performed in batch, continuous, or semi-continuous mode.

The curable polymer reinforcement material as described in the invention is preferably a liquid that having a viscosity of from about 20 centipoise to about 5000 centipoise, preferably from about 25 centipoise to about 3000 centipoise, and preferably from about 50 centipoise to about 1000 centipoise.

Following coating of the substrate, the curable polymer reinforcement material is partially cured (“B-staged”). This partial curing step is then followed by making a connection between the solder-bumped structure and a printed circuit board or array of attachment pads. Typically, making the connection between the solder-bumped structure and the printed circuit board or array of attachment pads is carried out by melting the solder bump such that intimate contact is achieved between the solder bump material and the electrical connection on the printed circuit board. This is designated as a “reflow step” (e.g. heating the assembly to a temperature high enough to melt at least a portion of the material constituting the solder bump in order to achieve a robust contact between the solder bump and the electrical contacts of the printed circuit board). It should be noted that additional curing of the polymer reinforcement material may occur during this reflow step. In one embodiment, the “B-staged” curable polymer reinforcement material becomes fully cured during the reflow step. Alternatively, the “B-staged” polymer reinforcement material may be fully cured in a step subsequent to the reflow step. The step in which the polymer reinforcement material is fully cured may be performed at a temperature above the melting point of the at least one solder bump. Alternately, the step in which the polymer reinforcement material is fully cured may be performed at a temperature below the melting point of the at least one solder bump.

It is to be stressed that the method of the present invention comprises a discrete and independent partial curing step in which the curable polymer reinforcement material in contact with the solder-bump on a substrate is partially cured to provide a solder-bumped structure. The connection between the solder-bumped structure and a printed circuit board or array of attachment pads is then created, and thereafter the partially cured curable polymer reinforcement material is fully cured. Typical curing methods include thermal cure, UV light cure, microwave cure, combinations thereof, and the like. A preferred method of partially curing (“B-staging”) the curable polymer reinforcement material is carried out by heating at a temperature in a range of from about 50° C. to about 250° C., more typically in a range of from about 80° C. to about 225° C., under vacuum in a range from about 1 atmosphere to about 1 millitorr, more typically in a range from about 200 torr to 1 torr. In addition, partial curing (B-staging) may typically occur over a time period in a range between about 30 seconds and about 5 hours, and more typically in a range between about 90 seconds and about 30 minutes. As noted, in one embodiment, additional curing of the polymer reinforcement material is effected during a solder reflow process. In another embodiment the cured polymer reinforcement material is post-cured at a temperature in a range from about 50° C. to about 250° C., more typically in a range from about 75° C. to about 200° C., over a period in a range from about 10 seconds to about 4 hours after the solder interconnection has been made between the device and the printed circuit board.

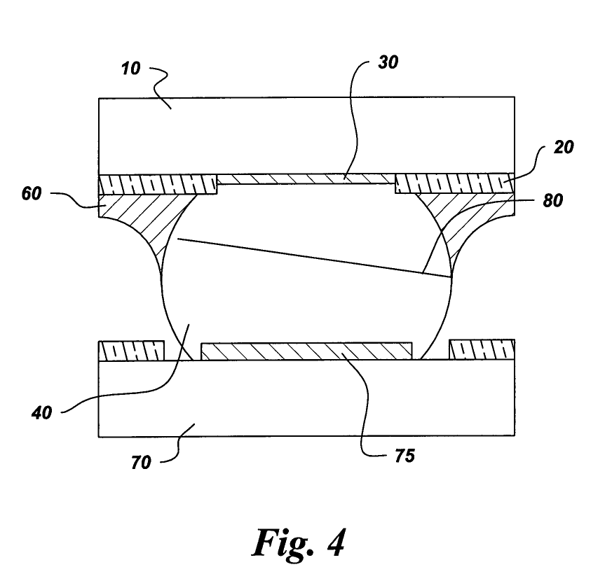

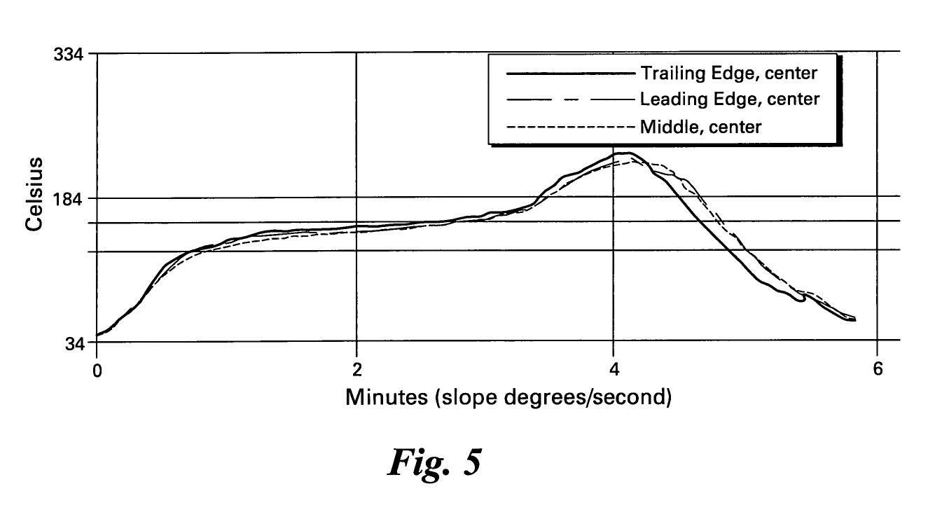

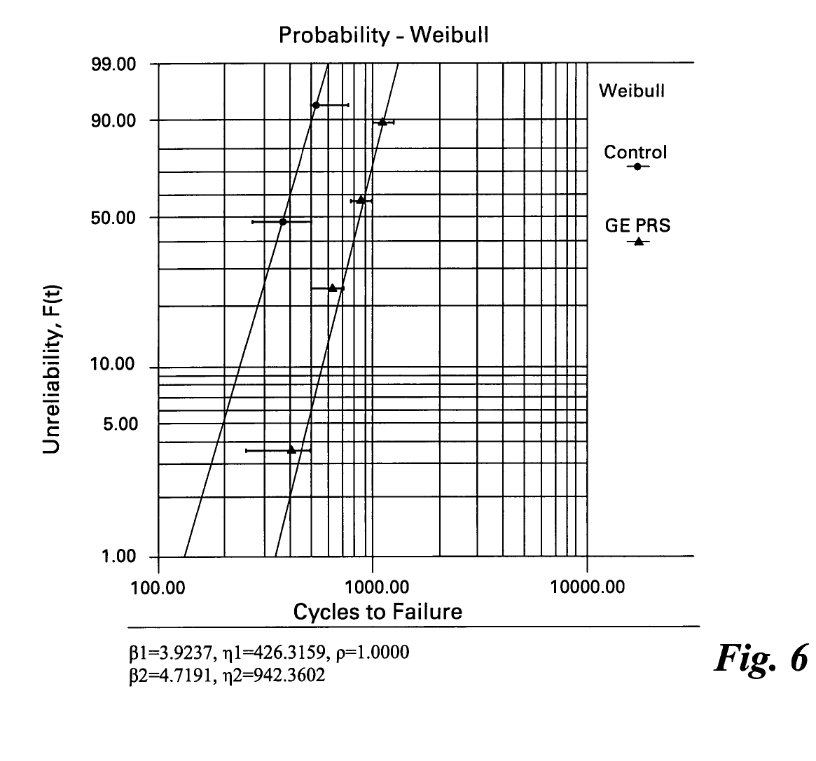

FIGS. 1-4 illustrate various aspects and embodiments of the present invention. FIGS. 1-3 illustrate stages in the process of preparing an electronic device according to the method of the present invention. FIG. 4 illustrates a reinforced solder joint in an electronic device according to the present invention. As illustrated in FIG. 1, the curable polymer reinforcement material 50 is coated onto a predetermined portion of the substrate 10 to form a layer of the curable polymer reinforcement material on the substrate, said layer contacting the exposed surface of said at least one solder-bump 40 using techniques that are known to those skilled in the art. Exemplary methods of coating include, but are not limited to, dispensing, printing, spin-coating, and the like. The curable polymer reinforcement material 50 is used to contact the substrate comprising at least one solder bump 40 to form a layer, wherein the layer has a thickness in a range corresponding to from about 5 percent to about 100 percent of the height of the at least one solder bump. In the embodiment of the present invention illustrated in FIG. 1 the thickness of the layer of the polymer reinforcement material is approximately the height of the individual solder bumps present.

Upon partial curing, also referred to a “B-staging”, the volume occupied by the curable polymer reinforcement material 50 is typically observed to be shrink as the material cures to afford the partially cured polymer reinforcement material 55. Thus in the embodiment shown in FIG. 2, the thickness of the layer of partially cured polymer reinforcement material 55 is typically less than the height of the solder bumps 40. FIGS. 1 and 2 illustrate an embodiment of the invention in which the curable polymer reinforcement material 50 is initially present as a layer having a thickness approximately equal to the height of the solder bumps 40 present. In the embodiment illustrated by FIGS. 1 and 2 partial curing of the structure shown in FIG. 1 results in shrinkage of the layer comprising the partially cured polymer reinforcement material 55 to a thickness substantially less than the height of the solder bumps 40 (See FIG. 2).

In one embodiment, following partial curing, the solder-bumped structure illustrated by FIG. 2 comprising the partially cured polymer reinforcement material 55 is connected to a printed circuit board or an array of attachment pads 70 and the entire structure is heated, thereby fully curing the partially cured polymer reinforcement material to provide an electronic device comprising a fully cured polymer reinforcement material 60. Electrical contact between the solder-bumped structure and the printed circuit board or array of attachment pads is provided by the contact between the exposed portion of the solder bumps 40 present in the solder-bumped structure and a corresponding electrical contact 75 (FIG. 4) on the printed circuit board or array of attachment pads. During this process of connecting the solder-bumped structure to the printed circuit board or array of attachment pads the temperature is typically maintained above the melting point of the solder bumps present in the solder-bumped structure. This results in the formation of a solder joint which provides electrical contact between the solder-bumped structure and the printed circuit board or array of attachment pads. FIG. 4 illustrates a reinforced solder joint present in an electronic device prepared according to the invention. For purposes of this invention, the reinforced solder joint comprises the solder pad 30 (FIG. 4) the solder bump 40 (FIG. 4), the electrical contact 75 (FIG. 4) on the printed circuit board or array of attachment pads, and the fully cured polymer reinforcement material 60.

In addition to providing a robust electrical contact between the printed circuit board or array of attachment pad and the solder bumped structure, heating serves to fully cure the partially cured polymer reinforcement material 55 to provide a fully cured polymer reinforcement material 60. Typically, the height of the fully cured final reinforcement layer 60 (See FIG. 3) formed by the method of the present invention is from about 5 percent to about 100 percent of the height of the solder joint, more preferably from about 10 percent to about 50 percent of the height of the solder joint present in the electrical device comprising the reinforced interconnection. One skilled in the art will be able to judge the amount of the curable polymer reinforcement material to be dispensed onto the substrate in order to achieve a layer of fully cured polymer reinforcement material having a height between 5 and 100 percent of the height of the solder joint.

### EXAMPLES

The following examples are set forth to provide those of ordinary skill in the art with a detailed description of how the methods claimed herein are evaluated, and are not intended to limit the scope of what the inventors regard as their invention. Unless indicated otherwise, parts are by weight, temperature is in ° C.

### Example 1:

Preparation of functionalized colloidal silica (FCS) predispersion.

A functionalized colloidal silica predispersion was prepared by combining the following: 935 grams of isopropanol (Aldrich) was slowly added by stirring to 675 grams of aqueous colloidal silica (Nalco 1034A, Nalco Chemical Company or Snowtex OL, Nissan Chemical Co.,) containing 34 weight % of 20 nanometer particles of SiO₂ (Nalco 1034A) or 21 weight % of 50 nanometer SiO₂ particles (Snowtex OL). Subsequently, phenyl trimethoxysilane (PTS, 58.5 grams for Nalco 1034A, 22.0 grams for Snowtex OL ), (Aldrich), which was dissolved in 100 grams isopropanol, was added to the stirred mixture. The mixture was then heated to 80° C. for 1-2 hours to afford a clear suspension. The resulting suspension of functionalized colloidal silica was stored at room temperature. Multiple dispersions based on Nalco 1034 (see Table 1), having various levels of SiO₂ (from 10% to 30% by weight) were prepared for use in Example 2.

### Example 2:

Preparation of a concentrated dispersion of functionalized colloidal silica in methoxypropanol.

A 2000 milliliter flask round bottom was charged with 540 grams of each of the pre-dispersions, prepared in Example 1. Additional pre-dispersion compositions are shown in Table 1, below. 1-methoxy-2-propanol (750 grams) was then added to each flask. The resulting dispersion of functionalized colloidal silica was vacuum stripped at 60° C. and 60 millimeter Hg to remove about 1 liter of solvents. The vacuum was slowly decreased and solvent removal continued with good agitation until the dispersion weight had reached 140 grams in the case of materials based on Nalco 1034A or 80 grams for Snowtex OL cases. The clear dispersions of phenyl-functionalized colloidal silica contained 50% by weight SiO₂ and no precipitated silica. These dispersions were stable at room temperature for more than three months. The results in Table 1 show that a certain level of phenyl functionality is required in order to prepare a concentrated, stable FCS dispersion in 1-methoxy-2-propanol (Dispersions 1 through 5). The functionality level can be adjusted to achieve a clear, stable dispersion in methoxypropanol acetate. This adjustment indicated that optimization of functionality level permitted dispersions to be prepared in other solvents (Dispersions 6 and 7)

TABLE 1
Preparation of FCS Dispersions based on Nalco 1034A

| | Pre-dispersion | Final Dispersion | |
|---|---|---|---|
| | Composition | Concentration | |
| | (moles of PTS/ | (wt % SiO₂)/ | Dispersion Stability |
| Entry# | 100 g SiO₂) | wt % total solids) | (in methoxypropanol) |
| 1 | 0.028 moles/100 g | 50% Si02/63% | precipitated |
| 2 | 0.056 moles/100 g | 47% SiO2/60% | precipitated |
| 3 | 0.13 moles/100 g | 53% SiO2/66% | stable, clear |
| 4 | 0.13 moles/100 g | 60% SiO2/75% | stable, clear |
| 5 | 0.19 moles/100 g | 50% Si02/63% | stable, clear |
| 6 | 0.13 moles/100 g | 50% Si02/63% | (in methoxy propanol |
| | | | acetate) precipitated |
| 7 | 0.19 moles/100 g | 50% SiO₂/63% | (in methoxy propanol |
| | | | acetate) Stable, clear |

### Example 3:

Preparation of a dispersion of capped functionalized colloidal silica in epoxy resin.

A solution of 3.2 grams of epoxy cresol novolac (ECN 195XL-25 available from Sumitomo Chemical Co.), 1.84 grams of Epon 826 (available from Resolution Performance Products), 2.6 grams of novolac hardener (Tamanol 758 available from Arakawa Chemical Industries) in 3.0 grams of 1-methoxy-2-propanol was heated to about 50° C. A 7.12 grams portion of the solution was added, dropwise, to 10.0 grams of the FCS dispersion (see Table 1, entry #3, 50% SiO₂ in methoxypropanol), by stirring at 50° C. followed by additional methoxypropanol (3.6 grams). The clear suspension was cooled and a catalyst solution of N-methylimidazole, 60 microliters of a 25% w/w solution in methoxypropanol was added by stirring.

Test procedure:

The test part used to demonstrate the reliability improvement from the polymer reinforcement system was an electronic device classified as a Wafer Level Chip Scale Package (WLCSP). This WLCSP was a daisy chained test part that was utilized to monitor the electrical continuity after assembly and during reliability testing. The WLCSP consisted of a silicon die with a thin redistribution layer leading to a center-depopulated array of 192 solder bumps which were 0.2 millimeters (8 milli inches) in initial height and had a pitch of 0.4 millimeters (16 milli inches). The solder bump metallurgy was eutectic tin-lead (63%Sn/37%Pb).

The uncured polymer reinforcement formulation was dispensed onto each part using an EFD manual dispenser model 1000XL available from EFD Inc., East Providence, R.I. in combination with a 3 cubic centimeter syringe with a 30 gauge dispense tip. The settings for the dot dispense operation was 5 pounds per square inch of air pressure with a 0.1 second dwell time. A dot dispense array of 9 droplets was used to coat the entire WLCSP.

The B-staging process was done in a Blue M vacuum oven available from Blue M electric Co., Williamsport, Pa. with a J-Kem scientific digital vacuum regulator model 200 available from J-Kem Scientific Co., St. Louis, Mo. The B-stage conditions were 10 minutes at 95° C. under a vacuum of 100 mm mercury. Following the B-stage process a 10-minute cool down was used and the parts with B-staged material were packed into waffle packs for assembly.

Standard (control) and polymer reinforced WLCSP parts were used for direct comparison in assembly and reliability testing. The parts were assembled using the same surface mount technologies on a standard 4 layer FR4 printed circuit board (PCB). A MPM semi-automatic screen printer was used to deposit eutectic tin-lead solder paste on the PCB. The stencil used was a stainless steel stencil design having a 0.075 millimeters (3 milli inches) thickness and 0.2 millimeters (8 milli inches) square apertures manufactured by UTZ technologies. The MPM printer utilized a six-inch Permalex Edge stainless steel squeegee blade mounted at a 45-degree angle. Critical machine settings for the stencil printing operation were ten pounds of pressure and a print speed of 1.27 cm/second (0.5 inches/second) for uniform solder paste deposits. The solder paste for this experiment was Indium RMA-SMQ51AC, which is a rosin-based, mildly activated, eutectic tin-lead (63%Sn/37%Pb) formulation. The solder particles in the solder paste have a mesh size of −325/+500.

Following the stencil printing step a MRSI pick and place robot model number 505 available from Newport Inc., East Billerica, Mass. was used to align and place the component solder bumps to the array of attachment pads on the printed circuit board. The placement force used was 30g. Then the test parts and the PCB were sent through a reflow step where the solder melted such that mechanical and electrical connections were formed between the test part and PCB. The reflow oven used was a Zepher 4 zone convention oven. The reflow profile was standard for eutectic tin-lead solder metallurgies. The reflow profile had a time between 130° C. and 160° C. of 125 seconds, the time above 183° C. of 65 seconds, a maximum temperature rise/fall rate of 3° C./sec and a 220° C. peak temperature. Three k-type thermocouples were placed at the edge and middle of the circuit board to monitor the temperature of the reflow profile.

The daisy chained electrical design of the test part and the PCB allowed for electrical resistance testing through the circuit. The WLCSP test part had a nominal electrical resistance value of 10 ohms measured by a Fluke 179 true root-mean-square multimeter. During assembly or reliability testing a failed part was defined as either an ohm increase that was 50% or greater than the nominal value or a mega ohm reading. The polymer reinforcement system had no negative impact on assembly yield.

Reliability Testing

For the data presented, the height of the polymer reinforcement layer was 15 percent of the solder joint height between solder joints at the lowest point and wetted up the side of the solder joints to 50 percent of the solder joint height. Air to Air Thermal Shock testing was the main metric for testing the reliability of a WLCSP with polymer reinforcement versus without. A Ransco environmental chamber was used to expose the test parts to thermal excursions. The cycling extremes were 0° C. and 100° C. A twenty-minute total cycle time was used with 10 minutes at each extreme. Electrical resistance measurements were taken at 250 cycle increments at room temperature. FIG. 4 shows the reliability of the data which was analyzed by plotting unreliability function versus cycles to failure. It shows the mean or average time to failure for the two-parameter Weibull distributions (63% of the cdf) had increased from 426 cycles to failure for the control assemblies to 942 cycles to failure for the polymer-reinforced assemblies.

The invention has been described in detail with particular reference to preferred embodiments thereof, but it will be understood by those skilled in the art that variations and modifications can be effected within the spirit and scope of the invention.

What is claimed is:

1. A method of forming an electronic device comprising a reinforced interconnection, said method comprising the steps of:
(A) providing a substrate having at least one solder bump formed thereon, said solder bump comprising at least one exposed surface;
(B) coating a predetermined portion of the substrate with a curable polymer reinforcement material to form a layer of the curable polymer reinforcement material on the substrate, said layer contacting the exposed surface of said at least one solder bump;
(C) partially curing the curable polymer reinforcement material to provide a solder-bumped structure comprising a partially cured polymer reinforcement material; and
(D) making a connection between the solder-bumped structure formed in step (C) and a printed circuit board or array of attachment pads and fully curing the partially cured polymer reinforcement material to provide a reinforced interconnection.

2. The method according to claim 1 wherein the curable polymer reinforcement material comprises a B-staged material.

3. The method according to claim 1 wherein the curable polymer reinforcement material comprises a filler selected from the group consisting of fused silica, fumed silica, colloidal silica, and combinations thereof.

4. The method according to claim 3 wherein the filler comprises functionalized colloidal silica.

5. The method according to claim 1 wherein the curable polymer reinforcement material comprises a filler having a particle size of from about 1 nanometer to about 250 nanometers.

6. The method according to claim 1 wherein the curable polymer reinforcement material comprises an epoxy resin.

7. The method according to claim 1 wherein the curable polymer reinforcement material prior to curing has a viscosity in a range from about 20 centipoise to about 5000 centipoise.

8. The method according to claim 1 wherein said solder bump has a height, and wherein said layer has a thickness in a range corresponding to from about 5 percent to about 100 percent of the height of the at least one solder bump.

9. The method according to claim 1 wherein said fully curing comprises heating to a temperature above the melting point of the at least one solder bump.

10. The method according to claim 1 wherein said fully curing comprises heating to a temperature below the melting point of the at least one solder bump.

11. An electronic device made by the method of claim 1.

12. An electronic device comprising a solder bump array, attachment pad array, a printed circuit board and a fluxing medium, said solder bump array being prepared by a method, comprising the steps of:
(A) providing a substrate having at least one solder bump formed thereon, said solder bump comprising at least one exposed surface;
(B) coating a predetermined portion of the substrate with a curable polymer reinforcement material to form a layer of the curable polymer reinforcement material on the substrate, said layer contacting the exposed surface of said at least one solder bump; and
(C) partially curing the curable polymer reinforcement material to provide a solder bump array.

13. The device according to claim 12 wherein the polymer reinforcement material comprises a B-staged material and at least one filler having an average particle size of between about 1 nanometer and about 250 nanometers.

14. The device according to claim 12 wherein the filler is selected from the group consisting of fused silica, fumed silica, colloidal silica, and combinations thereof.

15. The device according to claim 12 wherein the filler is functionalized colloidal silica.

16. The device according to claim 12 wherein the polymer reinforcement material comprises an epoxy resin.

17. The method according to claim 12 wherein the curable polymer reinforcement material prior to curing has a viscosity in a range from about 20 centipoise to about 5000 centipoise.

18. The method according to claim 12 wherein said solder bump has a height, and wherein said coating has a thickness in a range corresponding to about 5 percent to about 100 percent of the height of the at least one solder bump.

19. The device according to claim 12 wherein the curing step comprises heating to a temperature above melting point of the at least one solder bump.

20. A method of forming an electronic device comprising a solder-bumped structure, said method consisting essentially of the steps of:
(A) providing a substrate having at least one solder bump formed thereon, said solder bump comprising at least one exposed surface;
(B) coating a predetermined portion of the substrate with a curable polymer reinforcement material to form a layer of the curable polymer reinforcement material on the substrate, said layer contacting the exposed surface of said at least one solder bump;
(C) partially curing the curable polymer reinforcement material to provide a solder-bumped structure; and
(D) making a connection between the solder-bumped structure to a printed circuit board or array of attachment pads and fully curing the curable polymer reinforcement material to provide an interconnection that is reinforced with fully cured polymer reinforcement material.

21. An electronic device comprising a solder bump array, attachment pad array, a printed circuit board and a fluxing medium, said solder bump array being prepared by a method, consisting essentially of the steps of:
(A) providing a substrate having at least one solder bump formed thereon, said solder bump comprising at least one exposed surface;
(B) coating a predetermined portion of the substrate with a curable polymer reinforcement material to form a layer of the curable polymer reinforcement material on the substrate, said layer contacting the exposed surface of said at least one solder bump; and
(C) partially curing the curable polymer reinforcement material to provide a solder bump array.
